(19) United States
(12) Patent Application Publication
(10) Pub. No.: US 2011/0309429 A1
(43) Pub. Date: Dec. 22, 2011

(54) NONVOLATILE SEMICONDUCTOR MEMORY DEVICE AND MANUFACTURING METHOD THEREOF

(75) Inventor: Masahiro KIYOTOSHI, Mie (JP)

(73) Assignee: KABUSHIKI KAISHA TOSHIBA, Tokyo (JP)

(21) Appl. No.: 13/016,333

(22) Filed: Jan. 28, 2011

(30) Foreign Application Priority Data
Jun. 16, 2010 (JP) 2010-137430

(51) Int. Cl. H01L 29/788; H01L 21/336; B82Y 30/00

(52) U.S. Cl. 257/321; 438/404; 977/943; 257/E29.3; 257/E21.422

(57) ABSTRACT

According to one embodiment, in a floating-gate type nonvolatile semiconductor memory device in which a tunnel dielectric film and a control gate electrode are connected between memory cells adjacent via a shallow trench isolation, each of a floating gate electrode and the control gate electrode includes an electric-field concentrated portion having a curvature on the tunnel dielectric film side. The electric-field concentrated portion of the floating gate electrode is formed over a forming position of a channel semiconductor. The electric-field concentrated portion of the control gate electrode is formed over a forming position of the shallow trench isolation.

### CROSS-REFERENCE TO RELATED APPLICATIONS

This application is based upon and claims the benefit of priority from the prior Japanese Patent Application No. 2010-137430, filed on Jun. 16, 2010; the entire contents of which are incorporated herein by reference.

### FIELD

Embodiments described herein relate generally to a nonvolatile semiconductor memory device and a manufacturing method thereof.

### BACKGROUND

In recent years, use of a nonvolatile semiconductor memory device as a storage has expanded to various products, and downsizing of the nonvolatile semiconductor memory device has been progressed for further higher bit density and suppression of manufacturing cost.

However, with the progress of the downsizing, problems occur such as an inter-cell interference due to a parasitic capacitance between adjacent cells, degradation of transistor characteristics, or the like.

### BRIEF DESCRIPTION OF THE DRAWINGS

FIG. 1 is a circuit diagram illustrating an example of a configuration of a memory cell portion of a NAND-type flash memory;

FIG. 2 is a cross-sectional view schematically illustrating an example of a configuration of a nonvolatile semiconductor memory device according to a first embodiment;

FIG. 3A to FIG. 3C are diagrams schematically illustrating an erase operation of the nonvolatile semiconductor memory device according to the first embodiment;

FIG. 4A to FIG. 4C are diagrams schematically illustrating a write operation of the nonvolatile semiconductor memory device according to the first embodiment;

FIG. 5 is a diagram illustrating a relationship between an applied voltage to a memory cell and an electric field generated in a tunnel dielectric film and a gate dielectric film according to the first embodiment;

FIG. 6A and FIG. 6B are diagrams illustrating a distribution state of voltage/electric field at the erase operation of the memory cells according to the first embodiment;

FIG. 7A and FIG. 7B are diagrams illustrating a distribution state of voltage/electric field at the write operation of the memory cells according to the first embodiment;

FIG. 8 is a diagram illustrating an example of degradation characteristics of a threshold voltage of the nonvolatile semiconductor memory device according to the first embodiment;

FIG. 9 is a diagram illustrating an example of a relationship between a curvature radius normalized in the tunnel dielectric film and an increasing rate of the electric field in the nonvolatile semiconductor memory device according to the first embodiment;

FIG. 10A to FIG. 16E are cross-sectional views schematically illustrating an example of a procedure of a manufacturing method of the nonvolatile semiconductor memory device according to the first embodiment;

FIG. 17 is a cross-sectional view schematically illustrating an example of a configuration of a nonvolatile semiconductor memory device according to a second embodiment;

FIG. 18 is a diagram illustrating a relationship between an applied voltage to a memory cell and an electric field generated in a tunnel dielectric film and a gate dielectric film according to the second embodiment;

FIG. 19A and FIG. 19B are diagrams illustrating a distribution state of voltage/electric field at an erase operation of the memory cells according to the second embodiment;

FIG. 20A and FIG. 20B are diagrams illustrating a distribution state of voltage/electric field at a write operation of the memory cells according to the second embodiment;

FIG. 21 is a cross-sectional view schematically illustrating an example of a configuration of a nonvolatile semiconductor memory device according to a third embodiment;

FIG. 22 is a diagram illustrating a relationship between an applied voltage to a memory cell and an electric field generated in a tunnel dielectric film and a gate dielectric film according to the third embodiment;

FIG. 23A and FIG. 23B are diagrams illustrating a distribution state of voltage/electric field at an erase operation of the memory cells according to the third embodiment;

FIG. 24A and FIG. 24B are diagrams illustrating a distribution state of voltage/electric field at a write operation of the memory cells according to the third embodiment;

FIG. 25A and FIG. 25B are cross-sectional views schematically illustrating an example of a configuration of a nonvolatile semiconductor memory device according to a fourth embodiment; and

FIG. 26 is a diagram illustrating an example of current-electric field characteristics of a tunnel dielectric film.

### DETAILED DESCRIPTION

In general, according to one embodiment, a nonvolatile semiconductor memory device is provided which includes a memory cell transistor including a stacked gate structure in which a gate dielectric film, a floating gate electrode, a tunnel dielectric film, and a control gate electrode are stacked in order on a channel semiconductor and a shallow trench isolation that separates adjacent memory cell transistors, and in which the tunnel dielectric film and the control gate electrode are connected between the memory cell transistors adjacent via the shallow trench isolation. Each of the floating gate electrode and the control gate electrode includes an electric-field concentrated portion having a curvature on the tunnel dielectric film side. The electric-field concentrated portion of the floating gate electrode is formed over the channel semiconductor. The electric-field concentrated portion of the control gate electrode is formed over the shallow trench isolation. An injection of electrons from the electric-field concentrated portion of the control gate electrode into the floating gate electrode and a removal of electrons from the electric-field concentrated portion of the floating gate electrode to the control gate electrode are controlled by a voltage applied between the channel semiconductor and the control gate electrode.

A nonvolatile semiconductor memory device and a manufacturing method thereof according to the embodiments will be explained below in detail with reference to the accompanying drawings. The present invention is not limited to these embodiments. The cross-sectional views of the nonvolatile semiconductor memory device used in the following embodiments are schematic ones, and the relationship between a thickness and a width of a film, a ratio of a thickness of respective films, and the like are different from realistic ones. Moreover, a film thickness illustrated below is an example and is not limited to this.

### First Embodiment

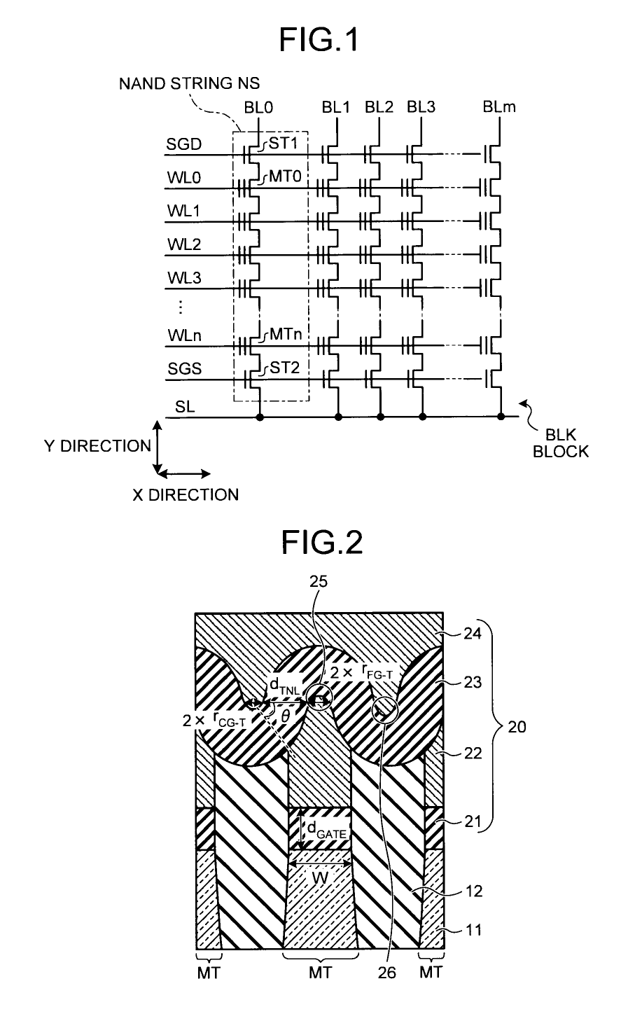

In the following embodiment, explanation is given for the case where a nonvolatile semiconductor memory device is applied to a NAND-type flash memory as an example. The NAND-type flash memory includes a memory cell portion in which memory cell transistors (hereinafter, simply memory cell in some cases) are arranged in an array, and a peripheral circuit portion that is arranged around the memory cell portion and controls the memory cells of the memory cell portion. FIG. 1 is a circuit diagram illustrating an example of the configuration of the memory cell portion of the NAND-type flash memory. FIG. 1 illustrates the circuit diagram of a block that is a unit of data erasing of the NAND-type flash memory. In FIG. 1, a right-and-left direction on the paper surface is defined as an X direction and a direction vertical to the X direction on the paper surface is defined as a Y direction.

A block BLK of the NAND-type flash memory includes (m+1) (m is an integer equal to or greater than 0) NAND strings NS arranged in order along the X direction. Each NAND string NS includes (n+1) (n is an integer equal to or greater than 0) memory cells MT0 to MTn connected in series in the Y direction and select transistors ST1 and ST2 that are arranged on both ends of a column of the (n+1) memory cells MT0 to MTn.

Each of the memory cells MT0 to MTn is composed of a field effect transistor that includes a stacked gate structure formed on a semiconductor layer to be a channel. The stacked gate structure includes a floating gate electrode formed on the semiconductor layer via a gate dielectric film and a control gate electrode formed on this floating gate electrode via a tunnel dielectric film.

The control gate electrodes of the memory cells MT0 to MTn forming the NAND string NS are connected to word lines WL0 to WLn each extending in the X direction, and the memory cells MTi (i=0 to n) in respective NAND strings NS are connected in common by the same word line WLi (i=0 to n). In other words, the control gate electrodes of the memory cells MTi in the same row in the block BLK are connected to the same word line WLi. The (m+1) memory cells MTi connected to the same word line WLi are treated as one page and writing and reading of data is performed in the page units.

The drains of the (m+1) select transistors ST1 in one block BLK are connected to bit lines BL0 to BLm, respectively, and the gates of the select transistors ST1 are connected to a select gate line SGD in common. In the similar manner, the sources of the (m+1) select transistors ST2 in one block BLK are connected to a source line SL in common, and the gates of the select transistors ST2 are connected to a select gate line SGS in common.

Although not shown, the drain of the select transistor ST1 is connected in common between the bit line BLj (j=0 to m) in one block BLK and the bit line BLj of a different block BLK. In other words, the NAND strings NS in the same column in a plurality of blocks BLK are connected by the same bit line BLj.

FIG. 2 is a cross-sectional view schematically illustrating an example of the configuration of the nonvolatile semiconductor memory device according to the first embodiment. FIG. 2 illustrates a partial cross section of the memory cell in a direction parallel to the X direction (extending direction of the word line) in FIG. 1. As shown in FIG. 2, a memory cell MT that includes a stacked gate structure 20 in which a gate dielectric film 21, a floating gate electrode 22, a tunnel dielectric film 23, and a control gate electrode 24 are stacked in order on an upper surface of a semiconductor substrate 11 to be a channel is formed. The channels, the gate dielectric films 21, and the floating gate electrodes 22 of the adjacent memory cells MT in the X direction are separated with each other by an isolation dielectric film 12 formed at predetermined intervals. The tunnel dielectric film 23 and the control gate electrode 24 are configured to be shared between the memory cells MT adjacent via the isolation dielectric film 12.

In the first embodiment, the floating gate electrode 22 and the control gate electrode 24 include tip portions 25 and 26 that are convex-shaped electric-field concentrated portions locally having a curvature, on the tunnel dielectric film 23 side. In other words, the floating gate electrode 22 includes the tip portion 25 having a convex shape on the tunnel dielectric film 23 side and the tip portion 25 has a predetermined curvature radius r_{FG-T}. Moreover, the control gate electrode 24 includes the tip portion 26 having a convex shape on the tunnel dielectric film 23 side and the tip portion 26 has a predetermined curvature radius r_{CG-T}. As will be described later, the curvature radii r_{FG-T} and r_{CG-T} of the tip portions 25 and 26 of the floating gate electrode 22 and the control gate electrode 24 are desirably 40% or less of the film thickness of the tunnel dielectric film 23.

Because the floating gate electrode 22 and the control gate electrode 24 include the tip portions 25 and 26 in this manner, for example, in the case of FIG. 2, the tunnel dielectric film 23 has a wave shape having a peak over a formation region of the memory cell MT and a valley over the isolation dielectric film 12. It is applicable to adjust the film thickness of both of the tunnel dielectric film 23 and the gate dielectric film 21 that controls a channel current so that the capacitances of both of them become approximately equal.

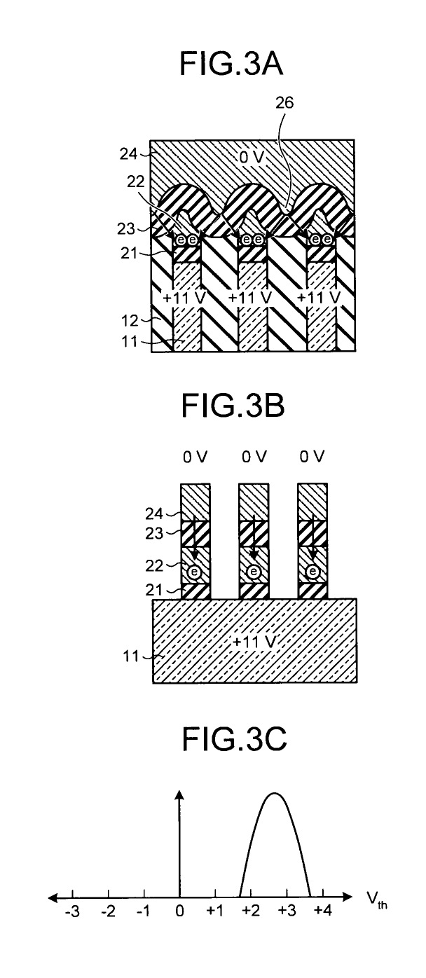

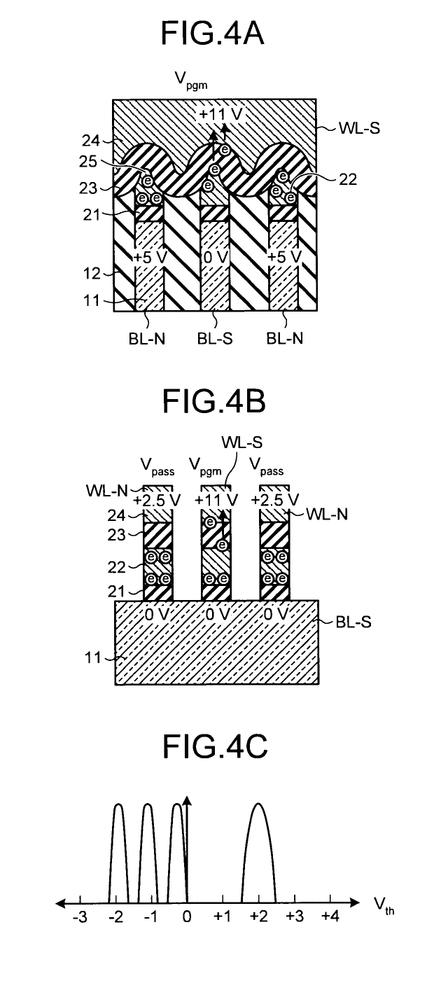

Next, the operation of the nonvolatile semiconductor memory device having such structure is explained. FIG. 3A to FIG. 4C are diagrams schematically illustrating an operation image of the nonvolatile semiconductor memory device in the first embodiment. FIG. 3A to FIG. 3C illustrate an erased state and FIG. 4A to FIG. 4C illustrate a written (program) state. FIG. 3A and FIG. 4A illustrate cross-sectional views in a direction parallel to the extending direction of the word line, FIG. 3B and FIG. 4B illustrate cross-sectional views in a direction vertical to the word line, and FIG. 3C and FIG. 4C illustrate states of a threshold voltage.

In the erase operation, as shown in FIG. 3A to FIG. 3C, a positive voltage (for example, +11 V) is applied to the semiconductor substrate 11 and the control gate electrode 24 is set to 0 V. Consequently, the electric field is concentrated on the tip portion 26 of the control gate electrode 24, electrons are injected into the floating gate electrode 22 from the tip portion 26 of the control gate electrode 24, and a threshold voltage Vₜₕ of the memory cell is shifted to the positive side. As shown in FIG. 3A, although the tip portion 26 of the control gate electrode 24 is located over the isolation dielectric film 12, electrons are injected from the tip portion 26 of the control gate electrode 24 into the floating gate electrodes 22 of adjacent memory cells on both sides.

On the other hand, in the write operation, as shown in FIG. 4A to FIG. 4C, a channel potential (substrate potential) of a selected bit line BL-S is lowered to 0 V and a channel potential of nonselected bit lines BL-N is set to +5 V, Vₚₐₛₛ (for example, +2.5 V) is applied to nonselected word lines WL-N, and a program voltage V_{pgm} (for example, +11 V) is applied to a selected word line WL-S. Consequently, the electric field is concentrated on the tip portion 25 of the floating gate electrode 22 of a selected bit present at an intersection of the selected bit line BL-S and the selected word line WL-S, electrons are released from the tip portion 25 of the floating gate electrode 22 to the selected word line WL-S (the control gate electrode 24), and the threshold voltage Vₜₕ of the memory cell is returned to the negative side. FIG. 4C illustrates the state of the threshold voltage in the case of a quaternary-data memory system capable of storing two bits in one memory cell. In the quaternary-data memory system, quaternary data defined by upper page data and lower page data is used, and movement of the threshold voltage is performed for distinguishing the erased state and the written state in the upper page with respect to the erased state and the written state in the lower page.

Moreover, in a read operation, current is measured that flows in the channel when a voltage is applied between the drain of one select transistor ST1 and the source of the other select transistor ST2 of the NAND string NS in FIG. 1 and a read voltage is applied to the control gate electrode (word line WL). The case where the current does not flow, i.e., the case of the erased state is set to “1”, and the case where the current flows, i.e., the case of the written state is set to “0”.

In this manner, the way of moving the threshold voltage Vth in the first embodiment is opposite to a typical floating-gate type NAND flash memory. Moreover, the write/erase operations of exchanging electrons between the channel and the floating gate electrode 22 via the gate dielectric film 21 are not performed different from a typical flash memory, and the write/erase operations of exchanging electrons between the floating gate electrode 22 and the control gate electrode 24 via the tunnel dielectric film 23 are performed.

Next, the improvement effect of the write/erase characteristics in the first embodiment is explained. Only a two-dimensional capacitance between the control gate electrode, the floating gate electrode, and the channel semiconductor is taken into consideration for easy understanding. As illustrated in the estimation below, in the structure in the first embodiment, the capacitance of the gate dielectric film 21 tends to become small compared to the capacitance of the tunnel dielectric film 23, which is different from a typical flash memory. This is desirable in view of improving controllability of the channel current, however, the electric field generated in the tunnel dielectric film 23 becomes small and thereby the write/erase characteristics may deteriorate. However, in the structure in the first embodiment, because the floating gate electrode 22 and the control gate electrode 24 include the tip portions 25 and 26 having a convex shape on the tunnel dielectric film 23 side, the write/erase characteristics of the memory cell MT are improved by electric field concentration on the tip portions 25 and 26.

In this example, the interface between the floating gate electrode 22 and the tunnel dielectric film 23, and the interface between the tunnel dielectric film 23 and the control gate electrode 24 are formed by a curved surface having a curvature. When the distance from the center of the tip portion 25 of the floating gate electrode 22 to an arbitrary point of the tunnel dielectric film 23 is r and the relative permittivity of the tunnel dielectric film 23 is ∈, an electric field E_{TNL} generated by a charge amount Q accumulated in the tunnel dielectric film 23 is expressed by the following equation (1).

$${E}_{TNL} = \frac{Q}{2 π {ɛ}_{0} ɛ r} \qquad ( 1 )$$

Moreover, a voltage V_{TNL} between the control gate electrode 24 and the floating gate electrode 22 can be calculated as the following equation (2) from equation (1), in which the thickness of the tunnel dielectric film 23 is d_{TNL} and the curvature radius of the tunnel dielectric film 23 is r_{TNL}.

$${V}_{TNL} = \frac{Q}{2 {πɛ}_{0} ɛ} ln ( \frac{{r}_{TNL} + {d}_{TNL}}{{r}_{TNL}} ) \qquad ( 2 )$$

A capacitance C_{TNL} of the tunnel dielectric film 23 can be approximately expressed by the following equation (3), in which the curvature radius of the tip portion 25 of the floating gate electrode 22 is r_{FG-T}, the curvature radius of the tip portion 26 of the control gate electrode 24 is r_{CG-T}, and an angle formed by a straight line drawn from the center of the tip portion 26 of the control gate electrode 24 to the end portion (boundary part of the floating gate electrode 22 of the adjacent memory cell MT, the isolation dielectric film 12, and the tunnel dielectric film 23) of the floating gate electrode 22 of the adjacent memory cell MT and a surface that passes the center of the tip portion 26 of the control gate electrode 24 and is parallel to the substrate surface is θ.

$$\begin{matrix}{C}_{TNL} = \sum \frac{2 π {ɛ}_{0} ɛ}{ln ( \begin{matrix}{r}_{TNL} + {d}_{TNL} \\ {r}_{TNL}\end{matrix} )} \\ = \frac{π {ɛ}_{0} ɛ}{ln ( \begin{matrix}{r}_{FG - T} + {d}_{TNL} \\ {r}_{FG - T}\end{matrix} )} + 2 \frac{{ɛ}_{0} ɛ θ}{ln ( \begin{matrix}{r}_{CG - T} + {d}_{TNL} \\ {r}_{CG - T}\end{matrix} )}\end{matrix} \qquad ( 3 )$$

On the other hand, when the channel width of one memory cell MT is W and the film thickness of the gate dielectric film 21 is d_{GATE}, a capacitance C_{GATE} of the gate dielectric film 21 is expressed by the following equation (4).

$${C}_{GATE} = \frac{{ɛ}_{0} ɛ W}{{d}_{GATE}} \qquad ( 4 )$$

Moreover, when the voltage applied between the control gate electrode 24 and the semiconductor substrate 11 (channel) is V, a voltage V_{GATE} applied to the gate dielectric film 21 is expressed by the following equation (5) and the voltage V_{TNL} applied to the tunnel dielectric film 23 is expressed by the following equation (6).

$$\begin{matrix}{V}_{GATE} = \frac{{C}_{TNL}}{{C}_{GATE} + {C}_{TNL}} V & ( 5 ) \\ {V}_{TNL} = \frac{{C}_{GATE}}{{C}_{GATE} + {C}_{TNL}} V & ( 6 )\end{matrix}$$

Therefore, when the voltage V_{TNL} is applied between the floating gate electrode 22 and the control gate electrode 24, the electric field E_{TNL} generated in the tunnel dielectric film 23 can be expressed by the following equation (7).

$${E}_{TNL} = \frac{{V}_{TNL}}{{r}_{TNL} ln ( \begin{matrix}{r}_{TNL} + {d}_{TNL} \\ {r}_{TNL}\end{matrix} )} \qquad ( 7 )$$

Moreover, when the voltage V_{GATE} is applied between the semiconductor substrate 11 (channel) and the floating gate electrode 22, an electric field E_{GATE} generated in the gate dielectric film 21 can be expressed by the following equation (8).

$${E}_{GATE} = \frac{{V}_{GATE}}{{d}_{GATE}} \qquad ( 8 )$$

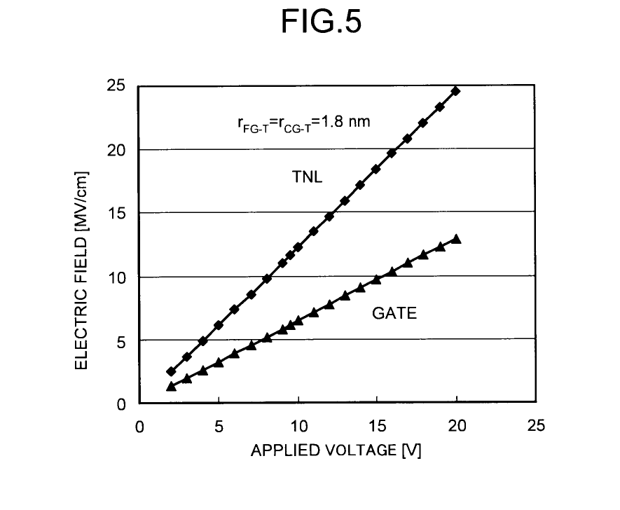

FIG. 5 is a diagram illustrating a relationship between the applied voltage to the memory cell and the electric field generated in the tunnel dielectric film and the gate dielectric film according to the first embodiment. In FIG. 5, a horizontal axis indicates a voltage (Applied Voltage) applied between the control gate electrode 24 and the channel semiconductor (the semiconductor substrate 11), and a vertical axis indicates a magnitude of the electric field generated in the tunnel dielectric film 23 or the gate dielectric film 21. Moreover, FIG. 5 illustrates the case in which a channel length L is 15 nm that is a half pitch and the curvature radii r_{FG-T} and r_{CG-T} of the tip portions 25 and 26 of the floating gate electrode 22 and the control gate electrode 24 are 1.8 nm. In FIG. 5, “TNL” indicates the electric field E_{TNL} generated in the tunnel dielectric film 23 and “GATE” indicates the electric field E_{GATE} generated in the gate dielectric film 21.

As shown in FIG. 5, the memory cell structure in the first embodiment is employed, i.e., the tip portions 25 and 26 having a curvature are provided in the floating gate electrode 22 and the control gate electrode 24, so that when a voltage is applied between the control gate electrode 24 and the channel semiconductor, the electric field E_{TNL} generated in the tunnel dielectric film 23 can be made higher than the electric field E_{GATE} generated in the gate dielectric film 21. Moreover, it is possible to lower the value of the applied voltage needed to make the electric field E_{TNL} generated in the tunnel dielectric film 23 be a desired value compared to a conventional structure.

In this manner, with the structure (structure capable of applying a manufacturing technology of a conventional floating-gate type flash memory) that is not largely different from a conventional floating-gate type memory cell structure, the electric field E_{TNL} generated in the tunnel dielectric film 23 can be amplified with respect to the electric field E_{GATE} generated in the gate dielectric film 21. In other words, the write/erase operations can be performed with a low operation voltage by utilizing the curvature of the floating gate electrode 22 and the control gate electrode 24.

Moreover, as described above, the capacitance of the gate dielectric film 21 that controls the channel current is approximately equal to or lower than the capacitance of the tunnel dielectric film 23, so that the applied voltage is not concentrated on the tunnel dielectric film 23 and a sufficient voltage is applied also to the gate dielectric film 21, enabling to control the channel current.

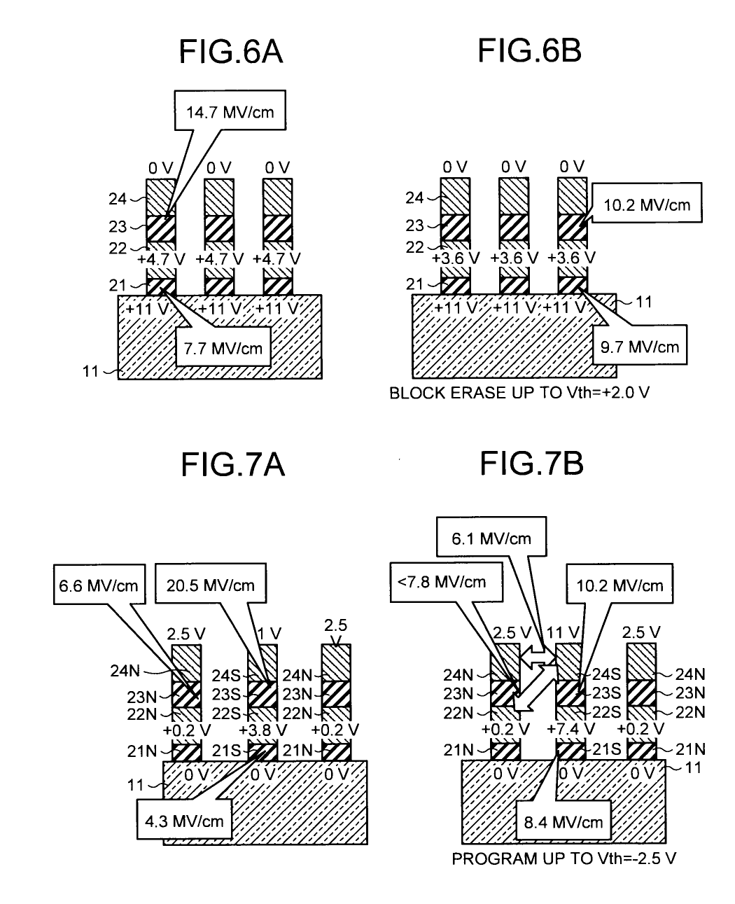

FIG. 6A and FIG. 6B are diagrams illustrating a distribution state of voltage/electric field at the erase operation of the memory cells according to the first embodiment, and FIG. 7A and FIG. 7B are diagrams illustrating a distribution state of voltage/electric field at the write operation of the memory cells according to the first embodiment. FIG. 6A and FIG. 7A illustrate states at the moment at which a voltage is applied to the memory cells, and FIG. 6B and FIG. 7B illustrate steady states after FIG. 6A and FIG. 7A, respectively. In these drawings, the case is illustrated in which the channel length L is 15 nm that is the half pitch and the curvature radii r_{FG-T} and r_{CG-T} of the tip portions 25 and 26 of the floating gate electrode 22 and the control gate electrode 24 are 1.8 nm.

As shown in FIG. 6A, at the erase operation, when the control gate electrode 24 is set to 0 V and +11 V is applied to the semiconductor substrate 11, the floating gate electrode 22 at the moment of voltage application becomes +4.7 V. Consequently, the electric field generated in the tunnel dielectric film 23 becomes 14.7 MV/cm, and the electric field generated in the gate dielectric film 21 becomes 7.7 MV/cm. For causing a tunnel current to flow between the control gate electrode 24 and the floating gate electrode 22, the electric field generated in the tunnel dielectric film 23 is desirably 10 MV/cm or more. Therefore, due to these electric fields, exchange of electrons between the channel semiconductor and the floating gate electrode 22 is not performed and electrons are injected from the control gate electrode 24 into the floating gate electrode 22. Then, due to the injection of electrons into the floating gate electrode 22, the electric field generated in the tunnel dielectric film 23 is relaxed to move to the steady state illustrated in FIG. 6B. At this time, the electric field generated in the tunnel dielectric film 23 becomes 10.2 MV/cm and the electric field generated in the gate dielectric film 21 becomes 9.7 MV/cm. Consequently, erasing can be performed up to the threshold voltage Vₜₕ of +2.0 V.

Moreover, as shown in FIG. 7A, at the write operation, a substrate potential is set to 0 V, Vₚₐₛₛ of +2.5 V is applied to a control gate electrode 24N of the nonselected bit, and the program voltage V_{pgm} of +11 V is applied to a control gate electrode 24S of the selected bit. Potentials of floating gate electrodes 22S and 22N of the selected bit and the nonselected bit at the moment of voltage application are +3.8 V and +0.2 V, respectively. With such voltage distribution, the electric field of 20.5 MV/cm is generated in a tunnel dielectric film 23S of the selected bit having a curvature. Consequently, electrons are removed from the floating gate electrode 22S to the control gate electrode 24S. With the removal of electrons from the floating gate electrode 22S of the selected bit, the electric field of the tunnel dielectric film 23S is relaxed to move to the steady state illustrated in FIG. 7B.

In the steady state illustrated in FIG. 7B, the potential of the floating gate electrode 22S of the selected bit becomes +7.4 V. With such voltage distribution, the electric field generated in the tunnel dielectric film 23S of the selected bit becomes 10.2 MV/cm. Consequently, writing can be performed up to the threshold voltage of −2.5 V in the selected bit.

The electric fields generated in a gate dielectric film 21S of the selected bit at the voltage application and at the steady state are 4.3 MV/cm and 8.4 MV/cm, respectively, which satisfy the condition of avoiding performance of exchanging electrons between the semiconductor substrate 11 and the floating gate electrode 22S. In addition thereto, as described above, the potential of the floating gate electrode 22S of the selected bit at the steady state is 7.4 V, and control of the channel current can be possible with this potential.

The electric field between the adjacent floating gate electrode 22N of the nonselected bit that is erased up to +2 V in which the electric field is the highest and the control gate electrode 24S of the selected bit is smaller than 7.8 MV/cm, which satisfies the condition of avoiding occurrence of erroneous writing to the floating gate electrode 22N of the nonselected bit due to the voltage applied to the control gate electrode 24S of the selected bit.

The electric field between the control gate electrode 24S of the selected bit and the adjacent control gate electrode 24N of the nonselected bit is 6.1 MV/cm, which satisfies the condition of avoiding flow of a leakage current therebetween.

Moreover, at the voltage application, the electric field generated in a tunnel dielectric film 23N of the nonselected bit is 6.6 MV/cm that is equal to or lower than 7 MV/cm. Consequently, at the voltage application, fluctuation of the voltage of the floating gate electrode 22N in the nonselected bit can be suppressed.

As described above, in the nonvolatile semiconductor memory device in the first embodiment, at the write/erase operations, the electric field E_{GATE} with which exchange of electrons does not occur between the gate dielectric film 21S and the semiconductor substrate 11 can be maintained while maintaining the electric field E_{TNL} with which the tunnel current can flow in the tunnel dielectric film 23S of the selected bit. Moreover, the electric field generated between components of each memory cell can be controlled to have a breakdown voltage with which leakage of current between the control gate electrodes 24S and 24N of the selected bit and the adjacent nonselected bit can be prevented and have a breakdown voltage with which erroneous writing between the control gate electrode 24S of the selected bit and the adjacent floating gate electrode 22N of the nonselected bit can be prevented. Furthermore, the electric field generated in the tunnel dielectric film 23N can be controlled so that the voltage of the floating gate electrode 22N of the nonselected bit does not fluctuate at the voltage application in the write operation. Consequently, the nonvolatile semiconductor memory device in the first embodiment can be operated also as a memory device.

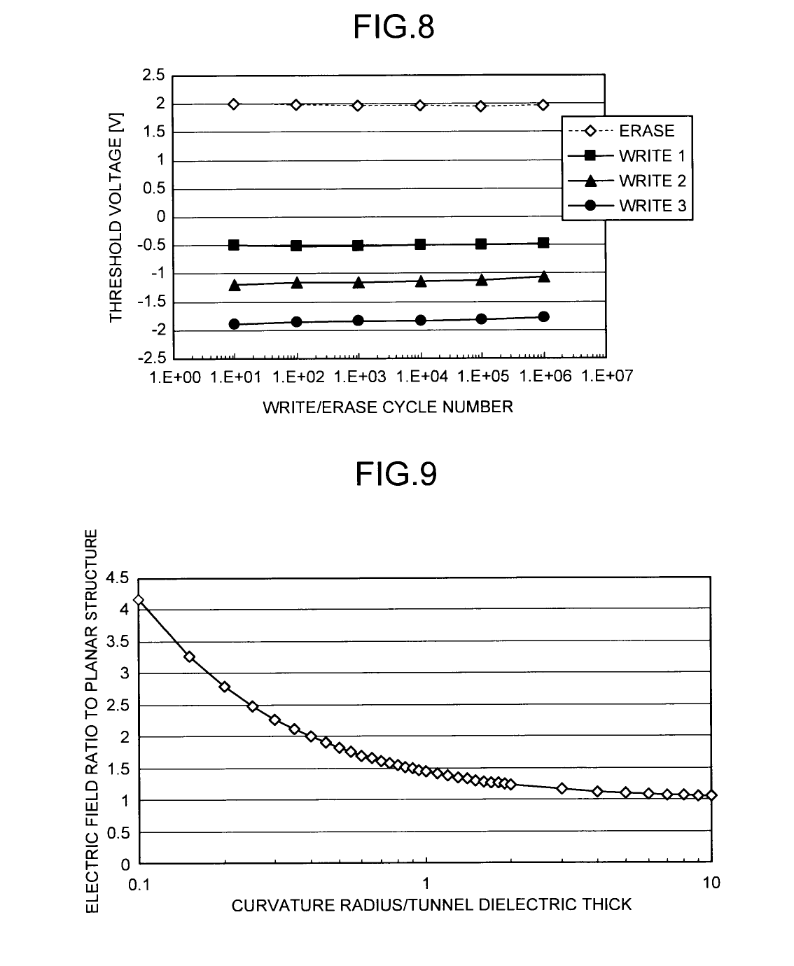

FIG. 8 is a diagram illustrating an example of degradation characteristics of the threshold voltage of the nonvolatile semiconductor memory device according to the first embodiment. In FIG. 8, a horizontal axis indicates a write/erase cycle number on a logarithmic scale and a vertical axis indicates the threshold voltage. As shown in FIG. 8, the threshold voltage shifts little with respect to 1000000 times of writing/erasing. This is because in a typical flash memory that performs the write/erase operations via the gate dielectric film 21, the threshold voltage shifts due to degradation of the gate dielectric film through repetition of the write/erase operations, however, in the structure in the first embodiment, the write/erase operations via the gate dielectric film 21 are not performed, so that there is substantially no degradation phenomenon of the gate dielectric film 21 occur even if the write/erase operations are repeated.

FIG. 9 is a diagram illustrating an example of a relationship between a curvature radius normalized in the tunnel dielectric film and an increasing rate of the electric field in the nonvolatile semiconductor memory device according to the first embodiment. In FIG. 9, a horizontal axis indicates the curvature radius (Curvature Radius/Tunnel Dielectric Thick; hereinafter, normalized curvature radius) of the floating gate electrode and the control gate electrode normalized with the tunnel dielectric film thickness on a logarithmic scale, and a vertical axis indicates the increasing rate (Electric Field Ratio to Planar Structure) of the electric field representing a ratio of the electric field obtained in the curvature structure to the electric field in a planar structure. As shown in FIG. 9, the increasing rate of the electric field increases as the normalized curvature radius becomes small. Specially, for increasing the increasing rate of the electric field to be more than twice, the normalized curvature radius is set to 0.4 or less. In other words, if the tip portions 25 and 26 are formed so that the curvature radii of the floating gate electrode 22 and the control gate electrode 24 are 40% or less of the thickness of the tunnel dielectric film 23, the electric field that is over twice of the electric field in the planar structure can be obtained. For example, when the film thickness of the tunnel dielectric film 23 is 8 nm, the curvature radii of the floating gate electrode 22 and the control gate electrode 24 are desirably 3.2 nm or less.

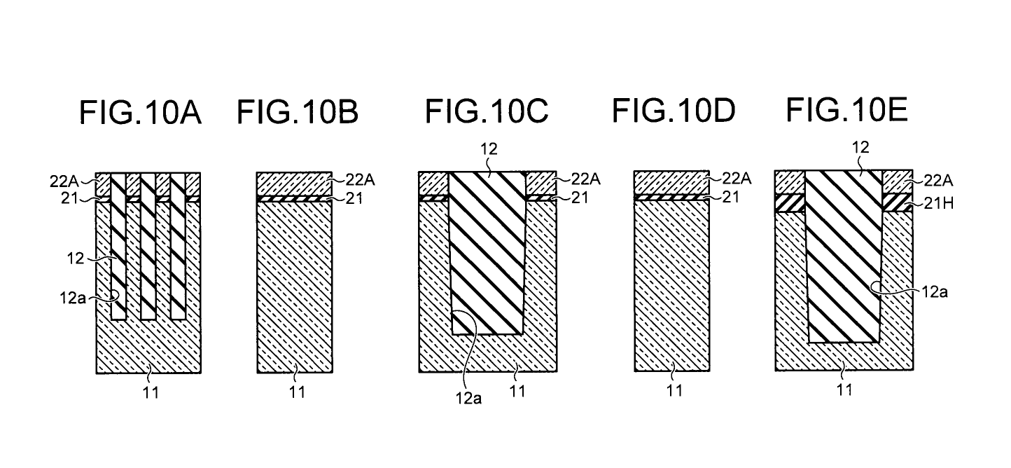

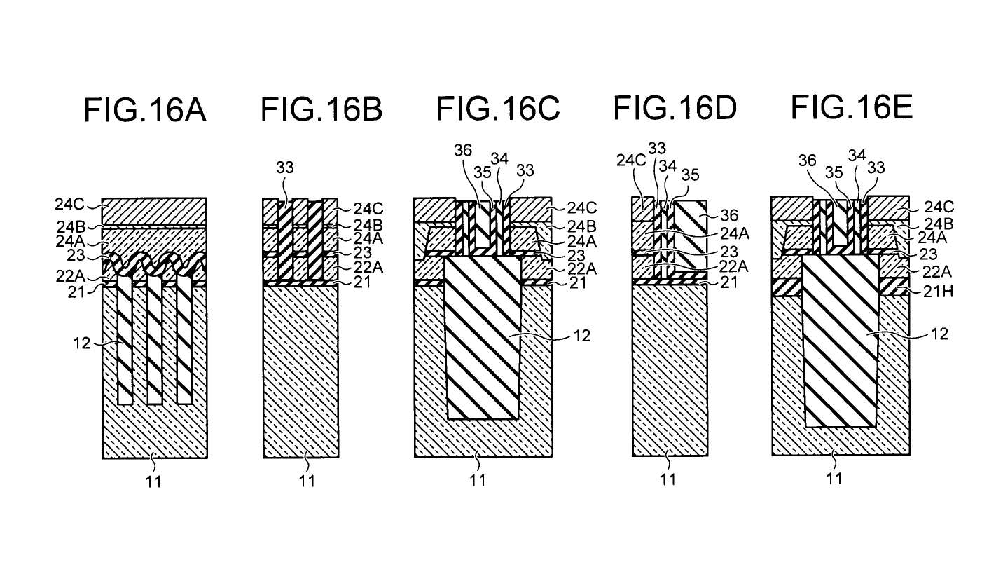

Next, the manufacturing method of the nonvolatile semiconductor memory device in the first embodiment is explained. FIG. 10A to FIG. 16E are cross-sectional views schematically illustrating an example of the procedure of the manufacturing method of the nonvolatile semiconductor memory device according to the first embodiment. In FIG. 10A to FIG. 16E, FIG. 10A to FIG. 16A are cross-sectional views of the memory cell portion in a direction vertical to the bit line, FIG. 10B to FIG. 16B are cross-sectional views of the memory cell portion on a memory-cell forming position in a direction (vertical to the word line) parallel to the bit line, FIG. 100 to FIG. 16C are cross-sectional views of a low-voltage-circuit forming region of the peripheral circuit portion in a direction vertical to the bit line, FIG. 10D to FIG. 16D are cross-sectional views of the low-voltage-circuit forming region in a direction parallel to the bit line, and FIG. 10E to FIG. 16E are cross-sectional views of a high-voltage-circuit forming region of the peripheral circuit portion in a direction vertical to the bit line.

In the peripheral circuit portion, a circuit that controls the memory cells in the memory cell portion is formed, and the high-voltage-circuit forming region and the low-voltage-circuit forming region are included. In the high-voltage-circuit forming region, a high-voltage-circuit is formed which includes a field effect transistor for applying a voltage pulse that is relatively higher than the power supply voltage, such as the program voltage V_{pgm} and an erase voltage Vₑᵣₐₛₑ, to the memory cell of the memory cell portion. Moreover, in the low-voltage-circuit forming region, a low-voltage-circuit is formed which includes a logic circuit such as a CMOS (Complementary Metal-Oxide-Semiconductor) transistor for which relatively high-speed and low-power-consumption performance is required. Therefore, the gate dielectric film is formed thick in the field effect transistor formed in the high-voltage-circuit forming region compared to the field effect transistor of the low-voltage-circuit forming region.

Moreover, in the memory cell portion, active areas are formed to be separated in a line and space shape by the isolation dielectric films 12, and in the following explanation, the case is explained as an example in which the half pitch of this line and space shaped pattern is 15 nm.

First, not-shown well and channel region are formed by ion implantation into the semiconductor substrate 11 such as a silicon substrate. Next, after a not-shown resist is applied to the whole surface of the semiconductor substrate 11 and patterning is performed so that only the high-voltage-circuit forming region of the peripheral circuit portion is open by a conventional lithography technique, the high-voltage-circuit forming region is recessed by the Reactive Ion Etching technique (RIE method) with the resist as a mask. After removing the resist, a dielectric film is formed on the whole surface of the semiconductor substrate 11, and the dielectric film in a region other than the high-voltage-circuit forming region is removed by using the lithography technique and the wet etching technique. Consequently, a gate dielectric film 21H is formed in the high-voltage-circuit forming region. As this gate dielectric film 21H, for example, a silicon thermally-oxidized film with a thickness of 20 nm can be used.

Next, the gate dielectric film 21 with a thickness of, for example, 8.8 nm is formed in the memory cell portion and the low-voltage-circuit forming region of the peripheral circuit portion. The gate dielectric film 21 is formed by forming a silicon thermally-oxidized film with a thickness of 8.3 nm by a thermal oxidation or a high-temperature oxygen radical oxidation, and thereafter nitriding the interface with the semiconductor substrate 11 by a heat treatment in nitric oxide (NO) and nitriding the upper surface of the silicon thermally-oxidized film by plasma nitridation. Consequently, the gate dielectric film 21H of the high-voltage-circuit forming region is also nitrided at the same time and the thickness thereof becomes 28 nm. In the structure of the nonvolatile semiconductor memory device in the first embodiment, the operation voltage of the memory cell can be made low as described above, so that the film thickness does not need to be 30 nm or more as the gate dielectric film of the high-voltage circuit of a typical flash memory.

Next, an N-type polycrystalline silicon film 22A doped with P to be the floating gate electrode of the memory cell and part of the gate electrode of the field effect transistor of the peripheral circuit portion is formed with a thickness of 25 nm by a film forming method such as the CVD (Chemical Vapor Deposition) method. Next, with the lithography technique (the Double Patterning technique or the Quadruple Patterning technique in which the Double Patterning technique is performed twice is used because of the processing for the half pitch of 15 nm, however, they do not have an essential relationship with the present embodiment, so that detailed explanation thereof is omitted) and the RIE method (a hard mask forming process for processing is performed, however, it is removed after the processing and it does not have an essential relationship with the present embodiment, so that detailed explanation thereof is omitted), an isolation trench 12a for STI (Shallow Trench Isolation) formation of the memory cell portion and the peripheral circuit portion is formed. Thereafter, the isolation trench 12a is completely filled with, for example, a TEOS (Tetraethoxysilane)/O₃ film, which is planarized by the CMP (Chemical Mechanical Polishing) to form the isolation dielectric film 12 (FIG. 10A to FIG. 10E).

Next, after a not-shown photoresist is applied to the whole surface of the semiconductor substrate 11 and patterning is performed so that the isolation dielectric film 12 of the memory cell portion is exposed by the lithography technique, the isolation dielectric film 12 of the memory cell portion is etched back by 10 nm by the RIE method. At this time, it is applicable that a portion to be the select transistor is not etched back. In this case, there is an advantage that processing of electrically connecting the control gate electrode and the floating gate electrode to be described later becomes easy. Consequently, the N-type polycrystalline silicon film 22A to be the floating gate electrode is exposed compared to the upper surface of the isolation dielectric film 12 at the memory-cell-transistor forming position.

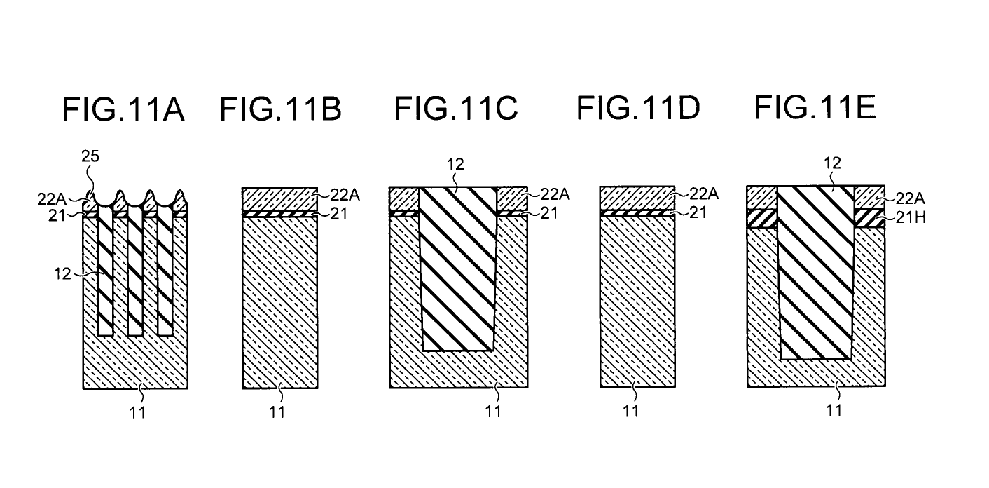

Thereafter, by a plasma oxidation treatment, the exposed N-type polycrystalline silicon film 22A is oxidized to a thickness of 5 nm to form an oxide film. The plasma oxidation treatment is desirably performed by a low temperature treatment of 400° C. or less, preferably, a room temperature treatment for suppressing diffusion of oxidized species. Next, only the upper portion of the N-type polycrystalline silicon film 22A is slimmed to process the upper end into a shape having a curvature. The curvature radius at this time is 1.8 nm. Moreover, the oxide film formed by the plasma oxidation treatment is recessed by the dry etching treatment using hydrogen fluoride gas and ammonia gas to make the surface of the N-type polycrystalline silicon film 22A of the memory cell portion and the peripheral circuit portion exposed (FIG. 11A to FIG. 11E). Consequently, the tip portion 25 having a convex shape upward is formed in the memory cell portion.

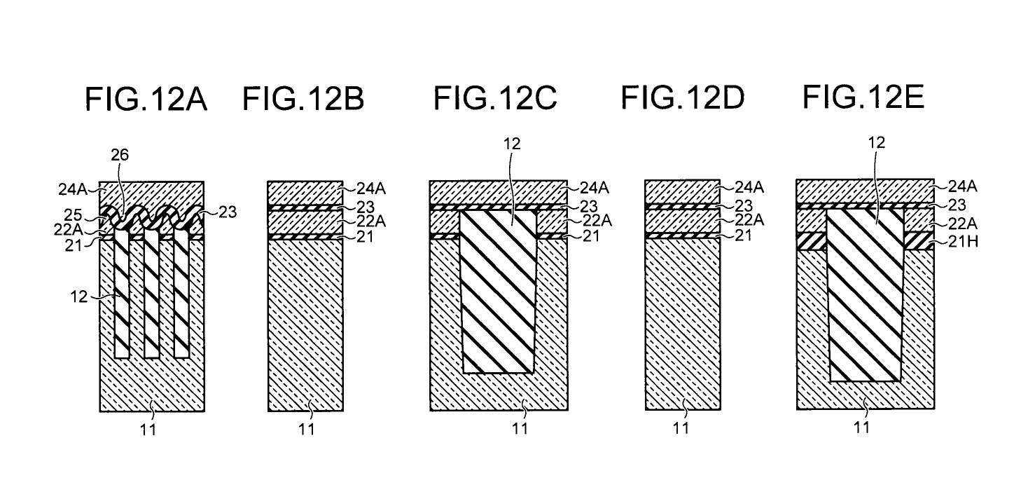

Next, the tunnel dielectric film 23 is formed on the N-type polycrystalline silicon film 22A. As the tunnel dielectric film 23, it is possible to use, for example, a silicon oxide film having a thickness of 10.4 nm formed by the ALD (Atomic Layer Deposition) method or a silicon oxide film such as an HTO (High Temperature Oxide) film formed by the LPCVD (Low Pressure CVD) method. The tunnel dielectric film 23 formed in such manner has an undulating shape in the memory cell portion due to the shape of the base N-type polycrystalline silicon film 22A. Next, an N-type polycrystalline silicon film 24A doped with P to be part of the control gate electrode is formed with a thickness of 40 nm on the tunnel dielectric film 23. Consequently, the tip portion 26 having a convex shape downward is formed at the valley position of the tunnel dielectric film 23, i.e., at the position over the isolation dielectric film 12 (FIG. 12A to FIG. 12E).

Thereafter, after applying a not-shown photoresist to the N-type polycrystalline silicon film 24A, patterning is performed so that a predetermined region in the gate-electrode forming position of the field effect transistor other than the memory cell portion is open by the lithography technique. Next, the N-type polycrystalline silicon film 24A and the tunnel dielectric film 23 are removed with the resist as a mask by the RIE method to form an opening 31 that reaches the N-type polycrystalline silicon film 22A. Consequently, the N-type polycrystalline silicon film 22A is exposed at a part of the peripheral circuit portion.

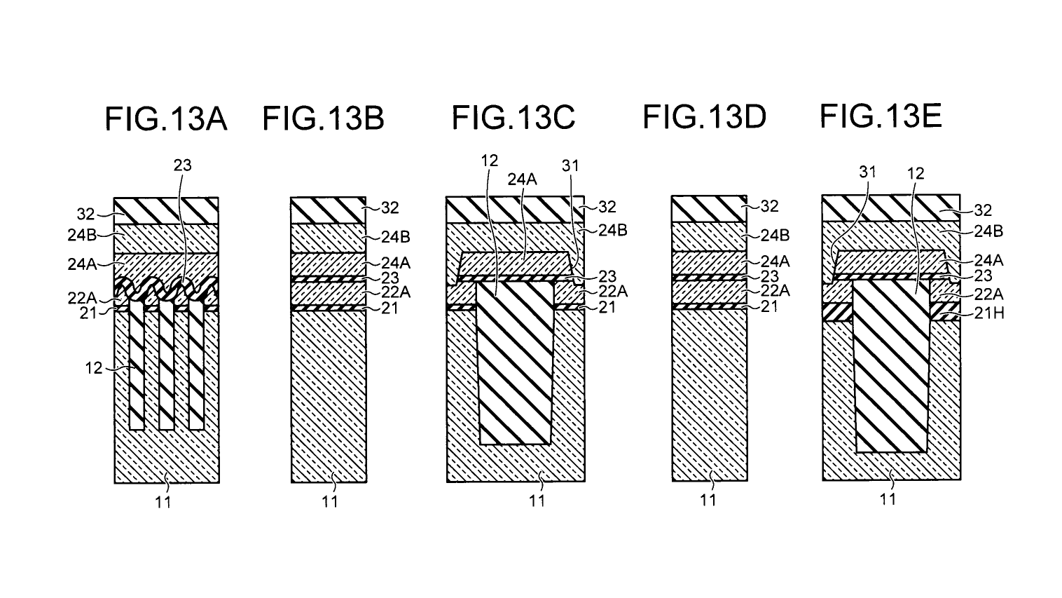

After removing the resist, an N-type polycrystalline silicon film 24B doped with P to be part of the control gate electrode is formed on the whole surface of the semiconductor substrate 11. Consequently, in the peripheral circuit portion, the N-type polycrystalline silicon film 24B is electrically connected to the N-type polycrystalline silicon film 22A in the opening 31. Thereafter, a mask film 32 to be a mask at the processing of the control gate electrode is formed on the whole surface on the N-type polycrystalline silicon film 24B. As the mask film 32, a silicon nitride film can be used (FIG. 13A to FIG. 13E).

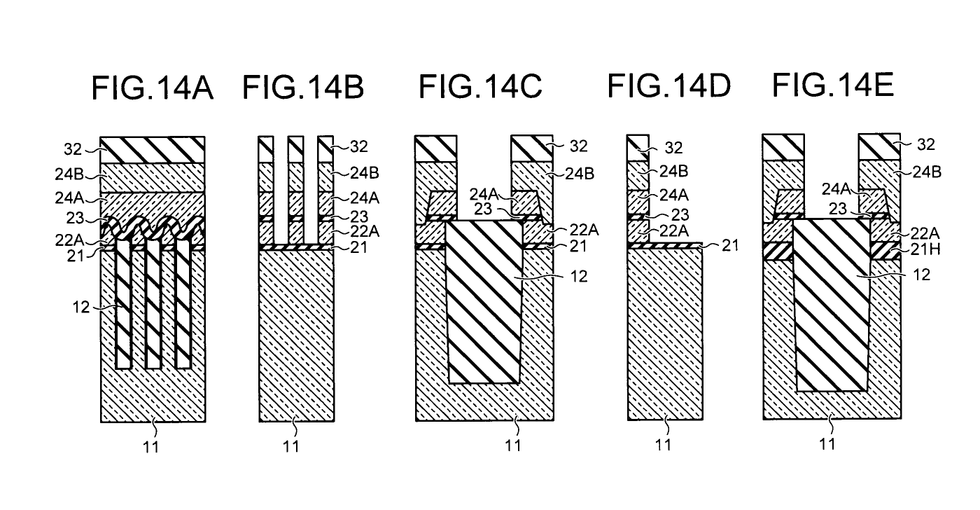

Next, with the lithography technique (the Double Patterning technique or the Quadruple Patterning technique is used because of the processing for the half pitch of 15 nm, however, they do not have an essential relationship with the present embodiment, so that detailed explanation thereof is omitted) and the RIE method, the mask film 32 is processed, and thereafter, the N-type polycrystalline silicon films 24B and 24A, the tunnel dielectric film 23, and the N-type polycrystalline silicon film 22A are processed by using the mask film 32. Consequently, in the memory cell portion, the stacked gate structures that extend in a direction orthogonal to the extending direction of the isolation dielectric film 12 are formed in a line and space shape, and in the peripheral circuit portion, the gate electrode of the field effect transistor is formed (FIG. 14A to FIG. 14E).

After removing the mask film 32, a silicon oxide film 33 to be a sidewall spacer is formed with a thickness of 10 nm by the ALD method. At this time, in the memory cell portion, the silicon oxide film 33 is embedded between the line and space shaped stacked gate structures, and in the peripheral circuit portion, the silicon oxide film 33 is formed on the side surface of the gate electrode.

Thereafter, a not-shown photoresist is applied to the whole surface on the semiconductor substrate 11, patterning is performed so that only a region in which a diffusion layer is formed is open by the lithography technique, and a not-shown diffusion layer is formed in the memory cell transistor by using the ion implantation technique. At this time, the diffusion layer can have a structure in which source/drain regions are provided for each memory cell as in a typical NAND-type flash memory, however, it is desirable that the source/drain regions are formed only in a not-shown select transistor arranged on both sides of the NAND string NS and the memory cell transistor is formed to have a sourceless/drainless structure. This is because injection/removal of electrons to the floating gate electrode 22 is not performed from the channel side in the structure in the present embodiment. Moreover, with the sourceless/drainless structure, a short channel effect of the memory cell transistor that is getting serious due to downsizing of the half pitch of 20 nm or less can be suppressed. Furthermore, read disturb/program disturb in which charges are written in the nonselected bit at the write/read operations can be suppressed by lowering electron concentration of the channel. Moreover, with the sourceless/drainless structure, in the floating gate electrode 22 having an inverted T-shaped structure in the present embodiment, the control gate electrode 24 can be made close to the channel by thinning the film thickness of most part of the floating gate electrode 22 of the memory cell, so that on/off control of the memory cell transistor can be performed by a fringe electric field of the control gate electrode 24.

Furthermore, a silicon oxide film 34 (preferably, HTO film or TEOS film) to be a sidewall spacer of the peripheral circuit portion is formed on the whole surface on the semiconductor substrate 11 by the LPCVD method. Thereafter, a not-shown photoresist is applied to the whole surface on the semiconductor substrate 11, patterning is performed by the lithography technique so that only a region in which a diffusion layer is formed is open, and a not-shown diffusion layer of the field effect transistor of the peripheral circuit portion is formed by using the ion implantation technique.

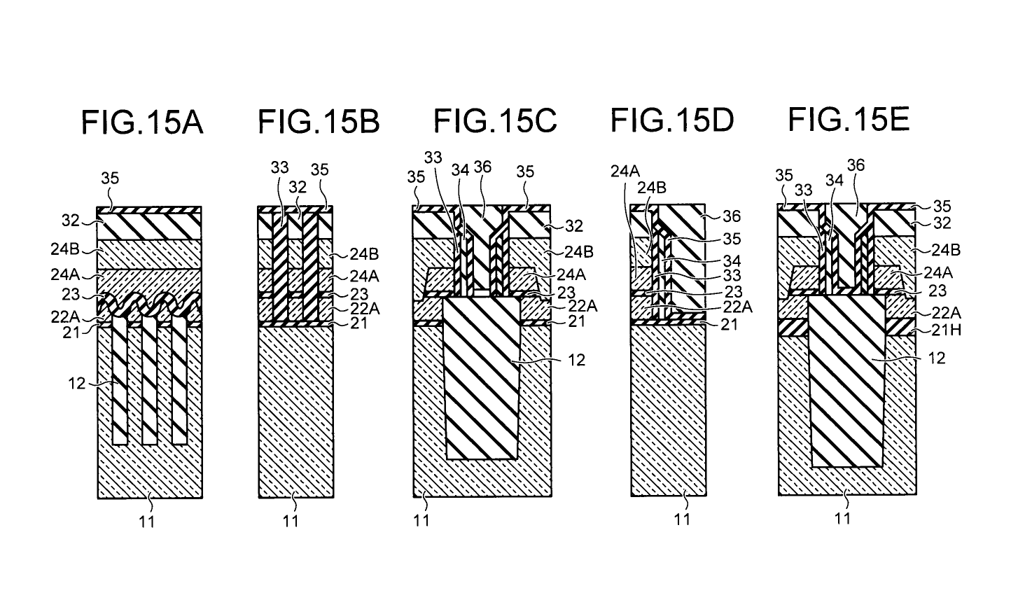

Next, a barrier nitride film 35 that suppresses oxidation of the control gate electrode is formed on the whole surface of the semiconductor substrate 11. As the barrier nitride film 35, for example, a silicon nitride film can be used. Thereafter, an inter-layer dielectric film 36, such as a TEOS/O₃ film, is formed to fill a space between the gate electrodes of the peripheral circuit portion, and the upper surface thereof is planarized by the CMP method (FIG. 15A to FIG. 15E).

Next, the barrier nitride film 35 and the mask film 32 formed on the control gate electrode of the memory cell portion and on the gate electrode of the peripheral circuit portion are removed by the RIE method, and a metal film that reacts with silicon to form silicide is formed on the whole surface of the semiconductor substrate 11 by the PVD (Physical Vapor Deposition) method. Thereafter, a silicidation annealing is performed to form a metal silicide film 24C on the upper portion of the N-type polycrystalline silicon film 24B (FIG. 16A to FIG. 16E). The metal silicide film 24C and the N-type polycrystalline silicon films 24A and 24B in the memory cell portion form the control gate electrode, and the metal silicide film 24C and the N-type polycrystalline silicon films 24A, 24B, and 22A in the peripheral circuit portion form the gate electrode of the field effect transistor. Consequently, the memory cell transistor and the field effect transistor of the peripheral circuit portion are formed. In the following process, a multilayer interconnection process is performed in the similar manner to a typical flash memory, however, this is not related to the present embodiment, so that explanation thereof is omitted.

The above explanation is one example, and the material system, the film thickness, and the processing method are not limited. For example, the substrate is not limited to a single-crystal silicon substrate and can be applied to an SOI (Silicon-On-Insulator) substrate (single-crystal semiconductor substrate of an SOI structure), or a polycrystalline semiconductor of a TFT (Thin-Film Transistor) structure or an amorphous semiconductor of the TFT structure. In the structure in the first embodiment, the erase operation is not performed from the substrate side, so that the SOI structure is easily applied, and application of the SOI structure brings an effect that suppression of junction leakage to the substrate and STI formation can be made easy. Moreover, it becomes easy to three-dimensionally stack memory layer on the substrate by employing the TFT structure.

Furthermore, in the above explanation, the memory cell portion and the peripheral circuit portion are formed on the substrate in the same process, however, it is possible to first form the peripheral circuit portion on the substrate and thereafter form the memory cell portion in the present embodiment on the peripheral circuit portion. Consequently, a memory cell occupancy can be significantly increased, so that an effect of enabling further downsizing is obtained. Moreover, in a typical three-dimensional structure, a problem arises in that the tunnel dielectric film 23 cannot be formed on the surface of the single-crystal semiconductor substrate itself by the thermal oxidation, however, the tunnel dielectric film 23 can be formed on the floating gate electrode 22 by the film forming process such as the LPCVD method and the ALD method in the SOI structure or the TFT structure, enabling to have an advantage of avoiding the constraints on the three-dimensional structure.

Moreover, as a metal silicide used for the control gate electrode and the gate electrode, it is possible to use tungsten silicide, cobalt silicide, nickel silicide, platinum nickel silicide, or the like. Furthermore, as the control gate electrode and the gate electrode, a polymetal electrode, in which tungsten is formed on a polycrystalline silicon film via barrier metal, can be used.

Furthermore, in the above explanation, a dielectric film obtained by nitriding upper and lower interfaces with a silicon thermally-oxidized film as a base is used as the gate dielectric film 21, however, it is possible to use an ONO film of SiO₂/SiN/SiO₂, an NONON film of SiN/SiO₂/SiN/SiO₂/SiN, or the like instead thereto. If SiN whose relative permittivity is seven is used, the gate dielectric film 21 can be physically thickened without lowering the capacitance of the gate dielectric film 21, so that leakage via the gate dielectric film 21 can be suppressed and thus the operation voltage range can be expanded.

In the first embodiment, the tip portions 25 and 26 are provided on the tunnel dielectric film 23 side of the floating gate electrode 22 and the control gate electrode 24. Therefore, an effect is obtained that when a voltage is applied between the control gate electrode 24 and the channel, the erase/write characteristics can be improved by the electric field concentration in the tunnel dielectric film 23. Moreover, the smaller the curvature radii r_{FG-T} and r_{CG-T} of the tip portions 25 and 26 become, the larger the electric field E_{TNL} applied to the tunnel dielectric film 23 becomes when the same voltage is applied at the write/erase operations, so that the tunnel current becomes easy to flow. Consequently, an effect is obtained that the voltage at write/erase operations can be lowered compared to the case of the memory cell having a planar structure. Furthermore, a portion to which writing is performed and a portion to which erasing is performed are independently arranged, so that degradation of the tunnel dielectric film 23 can be suppressed.

Moreover, in the memory cell having a structure in which electrons are exchanged between the channel semiconductor and the floating gate electrode 22 via the gate dielectric film 21, fatigue degradation such as occurrence of electron trapping due to high electric field operation occurs, and shift of the threshold voltage arises as a problem, however, in the first embodiment, exchange of electrons between the channel semiconductor and the floating gate electrode 22 is not performed, so that degradation of the gate dielectric film 21 that controls the channel current does not occur. Consequently, an effect is obtained that reliability can be easily ensured.

Furthermore, the floating gate structure is employed, so that electrons injected by a Fowler-Nordheim tunneling can be surely captured in the floating gate electrode 22 compared to the MONOS structure that appears promising for downsizing. Moreover, because electrons are rearranged in the floating gate electrode 22, an effect is obtained that the threshold voltage can be controlled with minimum charges without causing charge unbalance.

Moreover, in a conventional planar structural memory cell in which electron injection and erasing are performed on the floating gate electrode 22 via the tunnel dielectric film 23 from the control gate electrode 24 side, the structure needs to be such that the capacitance of the gate dielectric film 21 is larger than the capacitance of the tunnel dielectric film 23 for applying a sufficient voltage to the tunnel dielectric film 23. In such structure, whereas the sufficient voltage is applied to the tunnel dielectric film 23, it becomes difficult to apply a voltage to the gate dielectric film 21, so that a problem arises in that controllability of the channel current is reduced. However, in the first embodiment, the write/erase operations via the tunnel dielectric film 23 are performed by the electric field concentration utilizing the curvature and the capacitance of the gate dielectric film 21 itself does not need to be made significantly large. Therefore, the channel controllability of the gate dielectric film 21 is not reduced.

Furthermore, the required film thickness of the tunnel dielectric film 23 is smaller than the required film thickness of an inter-electrode dielectric film of a typical flash memory, so that the control gate electrode 24 can be formed between the tunnel dielectric films 23 even if the half pitch is shrunk to, for example, 20 nm or less. Consequently, the half pitch can be shrunk to 20 nm or less.

Moreover, a novel material for a semiconductor device manufacturing process, such as a high-k material, whose permittivity is higher than silicon oxide is not used for the gate dielectric film 21 or the tunnel dielectric film 23, so that electron trapping in the high-k material or degradation of characteristics of the memory cell transistor due to fixed charge does not arise as a problem. Furthermore, a novel element is not needed and the gate dielectric film 21 can be shared with the gate dielectric film 21 of the low-voltage-circuit forming region of the peripheral circuit portion, so that a manufacturing method similar to that for a conventional nonvolatile semiconductor memory device can be used.

Furthermore, in order to improve the write/erase characteristics by utilizing the curvature in a typical structure in which the tunnel dielectric film is formed between the channel semiconductor and the floating gate electrode, it is needed to use a structure in which the channel is extremely thin such as a GAA (Gate All Around) structure of a nanowire semiconductor, however, there is a problem in that it becomes difficult to ensure a sufficient on-current due to a channel width that becomes narrow inevitably in such structure. However, in the structure in the first embodiment, the channel width and the write/erase characteristics are independent, so that the channel width can be designed wide.

### Second Embodiment

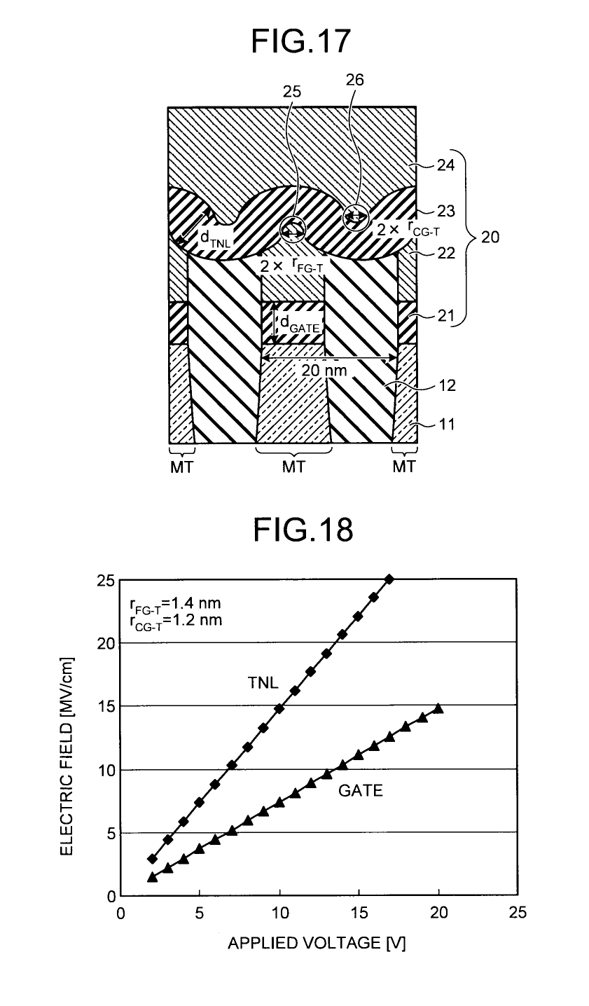

FIG. 17 is a cross-sectional view schematically illustrating an example of a configuration of a nonvolatile semiconductor memory device according to the second embodiment. The nonvolatile semiconductor memory device illustrated in FIG. 17 has the same structure as that in FIG. 2 in the first embodiment, and FIG. 17 illustrates the case in which the half pitch is 10 nm, the curvature radius r_{FG-T} of the tip portion 25 of the floating gate electrode 22 is 1.4 nm, and the curvature radius r_{CG-T} of the tip portion 26 of the control gate electrode 24 is 1.2 nm. Components that are the same as those in the first embodiment are given the same reference numerals and explanation thereof is omitted. The nonvolatile semiconductor memory device having such structure can be manufactured by the same method as in the first embodiment.

FIG. 18 is a diagram illustrating a relationship between the applied voltage to the memory cell and the electric field generated in the tunnel dielectric film and the gate dielectric film according to the second embodiment. In FIG. 18, a horizontal axis indicates a voltage (Applied Voltage) applied between the control gate electrode and the channel semiconductor (substrate), and a vertical axis indicates a magnitude of the electric field generated in the tunnel dielectric film and the gate dielectric film. In FIG. 18, “TNL” indicates the electric field E_{TNL} generated in the tunnel dielectric film 23 and “GATE” indicates the electric field E_{GATE} generated in the gate dielectric film 21.

Comparing FIG. 18 and FIG. 5, it is possible to generate a higher electric field E_{TNL} in the tunnel dielectric film 23 with a lower applied voltage compared to the case in the first embodiment by employing the memory cell structure in the second embodiment. Consequently, the value of the applied voltage necessary for making the electric field E_{TNL} generated in the tunnel dielectric film 23 to a desired value can be made further low compared to the case in the first embodiment.

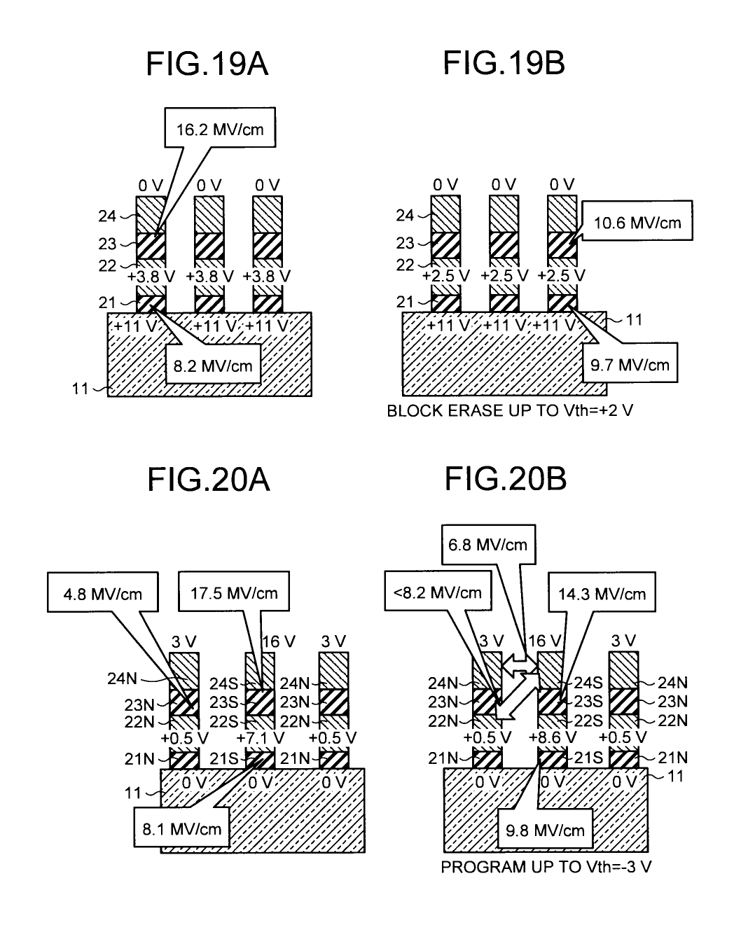

FIG. 19A and FIG. 19B are diagrams illustrating a distribution state of voltage/electric field at the erase operation of the memory cells according to the second embodiment, and FIG. 20A and FIG. 20B are diagrams illustrating a distribution state of voltage/electric field at the write operation of the memory cells according to the second embodiment. FIG. 19A and FIG. 20A illustrate states at the moment at which a voltage is applied to the memory cells, and FIG. 19B and FIG. 20B illustrate steady states after FIG. 19A and FIG. 20A, respectively.

As shown in FIG. 19A, at the erase operation, the control gate electrode 24 is set to 0 V and +11 V is applied to the substrate. The floating gate electrode 22 at the moment of voltage application becomes +3.8 V. Consequently, the electric field generated in the tunnel dielectric film 23 becomes 16.2 MV/cm, and the electric field generated in the gate dielectric film 21 becomes 8.2 MV/cm. In this example again, the electric field generated in the tunnel dielectric film 23 is 10 MV/cm or more, so that electrons can be injected from the control gate electrode 24 into the floating gate electrode 22. Injection of electrons into the floating gate electrode 22 is performed due to the electric field generated in the tunnel dielectric film 23, and the electric field generated in the tunnel dielectric film 23 is relaxed to move to the steady state illustrated in FIG. 19B. At this time, the potential of the floating gate electrode 22 becomes 2.5 V, so that the electric field generated in the tunnel dielectric film 23 becomes 10.6 MV/cm and the electric field generated in the gate dielectric film 21 becomes 9.7 MV/cm. Consequently, erasing can be performed up to the threshold voltage Vₜₕ of +2 V.

Moreover, as shown in FIG. 20A, at the write operation, the substrate potential is set to 0 V, Vₚₐₛₛ of +3 V is applied to the control gate electrode 24N of the nonselected bit, and the program voltage V_{pgm} of +16 V is applied to the control gate electrode 24S of the selected bit. Potentials of the floating gate electrodes 225 and 22N of the selected bit and the nonselected bit at the moment of voltage application are +7.1 V and +0.5 V, respectively. With such voltage distribution, the electric field of 17.5 MV/cm is generated in the tunnel dielectric film 23S of the selected bit having a curvature, and electrons are removed from the floating gate electrode 22S to the control gate electrode 24S. With the removal of electrons from the floating gate electrode 22S to the control gate electrode 24S, the electric field of the tunnel dielectric film 23S is relaxed to move to the steady state illustrated in FIG. 20B.

In the steady state illustrated in FIG. 20B, the potential of the floating gate electrode 22S of the selected bit becomes +8.6 V. With such voltage distribution, the electric field generated in the tunnel dielectric film 23S of the selected bit becomes 14.3 MV/cm. This electric field has a magnitude with which the tunnel current can be caused to flow in the tunnel dielectric film 23S. Consequently, writing can be performed up to the threshold voltage of −3 V in the selected bit.

The electric fields generated in the gate dielectric film 21S of the selected bit at the voltage application and at the steady state are 8.1 MV/cm and 9.8 MV/cm, respectively, which satisfy the condition of avoiding performance of exchanging electrons between the semiconductor substrate 11 and the floating gate electrode 22S. Moreover, the electric field between the adjacent floating gate electrode 22N of the nonselected bit that is erased up to +2 V in which the electric field is the highest and the control gate electrode 24S of the selected bit is smaller than 8.2 MV/cm, enabling to obtain the electric field with which erroneous writing to the floating gate electrode 22N of the nonselected bit due to the voltage applied to the control gate electrode 24S of the selected bit does not occur. Furthermore, the electric field between the control gate electrode 24S of the selected bit and the adjacent control gate electrode 24N of the nonselected bit is 6.8 MV/cm, so that the electric field can be suppressed to the electric field with which leakage current does not flow therebetween.

Moreover, at the voltage application in FIG. 20A, the electric field generated in the tunnel dielectric film 23N of the nonselected bit is 4.8 MV/cm. Consequently, at the voltage application, fluctuation of the voltage of the floating gate electrode 22N in the nonselected bit can be suppressed. As above, it is found that the nonvolatile semiconductor memory device having a structure in the second embodiment can also operate as a memory device.

The effect similar to the first embodiment can be obtained also in the second embodiment.

### Third Embodiment

When the half pitch is relatively large such as the half pitch equivalent to 18 nm generation, it becomes difficult to form a tip portion whose curvature radius is sufficiently small in the control gate electrode. Therefore, in the third embodiment, explanation is given for a structure of a nonvolatile semiconductor memory device in the case where the half pitch is relatively large.

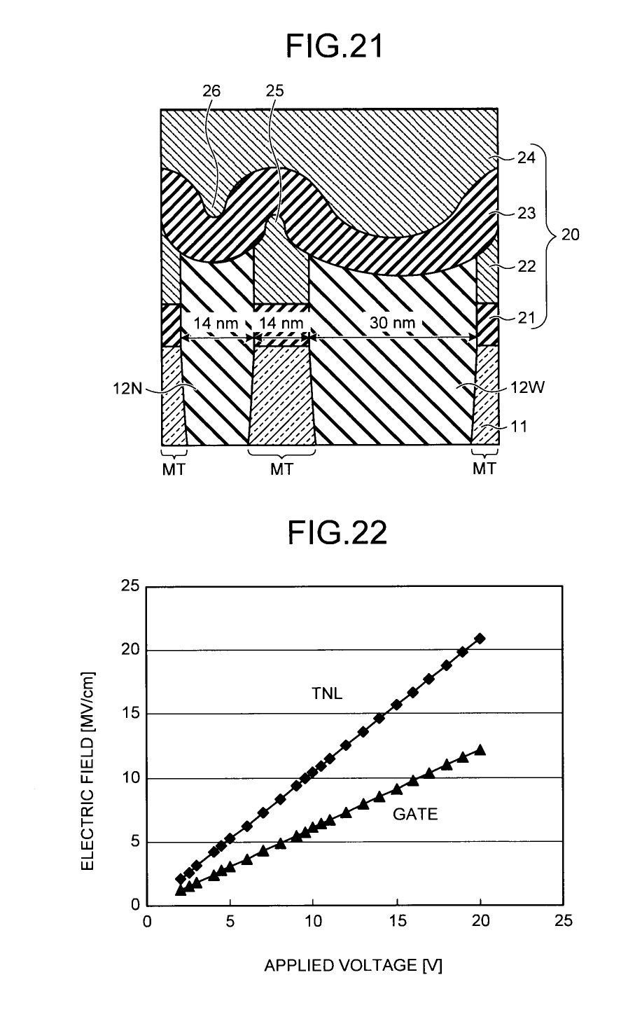

FIG. 21 is a cross-sectional view schematically illustrating an example of the configuration of the nonvolatile semiconductor memory device according to the third embodiment. This nonvolatile semiconductor memory device illustrated in FIG. 21 is the same as that illustrated in FIG. 2 in the first embodiment in the basic structure, however, is different in an interval (width of the STI formed between adjacent memory cells) between one memory cell MT and the adjacent memory cell MT to have a target half pitch as a whole average.

Specifically, when the width (channel width) of the memory cell MT in the word line direction is set to a first width that is narrower than the half pitch to be a target, an isolation dielectric film 12W arranged adjacent to one side of this memory cell MT in the word line direction is set to a second width wider than the half pitch to be a target and an isolation dielectric film 12N arranged adjacent to the other side is set to the first width that is narrower than the half pitch to be a target and is approximately the same as the memory cell MT, which is repeatedly arranged. In other words, the isolation dielectric film 12N having the first width and the isolation dielectric film 12W having the second width are alternately arranged between the memory cells MT having the first width arranged in the word line direction. Alternatively, the structure can be such that two memory cells MT and the isolation dielectric film 12N that is sandwiched between the memory cells MT and has the first width approximately the same as the channel width of the memory cell are paired and the pairs are arranged with intervals of the second width in the word line direction.

Consequently, the half pitch obtained by averaging the adjacent two memory cells MT, and the isolation dielectric film 12W and the isolation dielectric film 12N adjacent to these memory cells MT becomes the half pitch to be a target. For example, as shown in FIG. 21, when the width of the memory cell MT in the word line direction is 14 nm, the width of the wide isolation dielectric film 12W in the word line direction is 30 nm, and the width of the narrow isolation dielectric film 12N in the word line direction is 14 nm, the average half pitch of the nonvolatile semiconductor memory device in which the two memory cells MT and the two isolation dielectric films 12W and 12N are formed side by side becomes 18 nm.

In such structure, it is possible to form the tip portion 25 having a predetermined curvature radius in the floating gate electrode 22 of all of the memory cells MT. Moreover, the surface of the control gate electrode 24 on the tunnel dielectric film 23 side formed over the wide isolation dielectric film 12W has a large curvature radius, so that the tip portion is not formed thereon, however, the tip portion 26 having a predetermined curvature radius is formed in the similar manner to that explained in the first embodiment on the surface of the control gate electrode 24 on the tunnel dielectric film 23 side formed over the narrow isolation dielectric film 12N. Then, electrons are injected from the tip portion 26 of the control gate electrode 24 formed over the narrow isolation dielectric film 12N into the floating gate electrodes 22 of the memory cells MT adjacent on both sides of the isolation dielectric film 12N in the word line direction. Moreover, this narrow isolation dielectric film 12N is formed alternately with the wide isolation dielectric film 12W, so that electrons are injected from the tip portion 26 of the control gate electrode 24 formed over the narrow isolation dielectric film 12N into all of the memory cells MT formed on the semiconductor substrate 11. Components that are the same as those in the first embodiment are given the same reference numerals and explanation thereof is omitted. The nonvolatile semiconductor memory device having such structure can be manufactured by the same method as in the first embodiment.

FIG. 22 is a diagram illustrating a relationship between the applied voltage to the memory cell and the electric field generated in the tunnel dielectric film and the gate dielectric film according to the third embodiment. In FIG. 22, a horizontal axis indicates a voltage (Applied Voltage) applied between the control gate electrode and the channel semiconductor (substrate), and a vertical axis indicates a magnitude of the electric field generated in the tunnel dielectric film and the gate dielectric film. In FIG. 22, “TNL” indicates the electric field E_{TNL} generated in the tunnel dielectric film 23 and “GATE” indicates the electric field E_{GATE} generated in the gate dielectric film 21.

As shown in FIG. 22, in the third embodiment again, the electric field E_{TNL} generated in the tunnel dielectric film 23 when the voltage is applied can be made larger than the electric field E_{GATE} generated in the gate dielectric film 21 in the similar manner to the first embodiment.

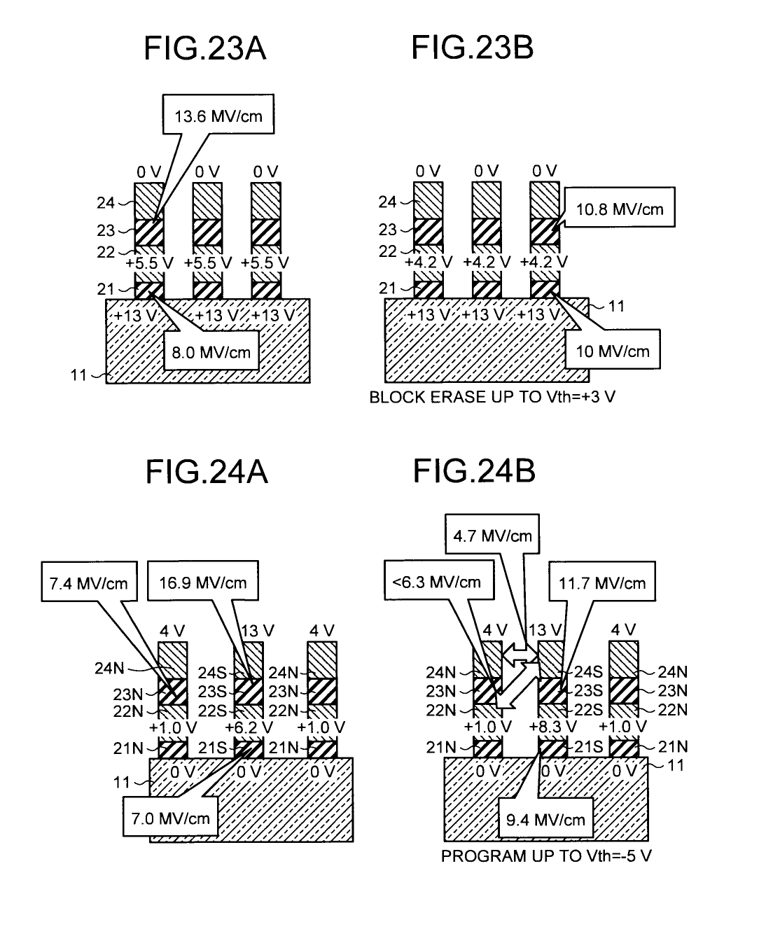

FIG. 23A and FIG. 23B are diagrams illustrating a distribution state of voltage/electric field at the erase operation of the memory cells according to the third embodiment, and FIG. 24A and FIG. 24B are diagrams illustrating a distribution state of voltage/electric field at the write operation of the memory cells according to the third embodiment. FIG. 23A and FIG. 24A illustrate states at the moment at which a voltage is applied to the memory cells, and FIG. 23B and FIG. 24B illustrate steady states after FIG. 23A and FIG. 24A, respectively.

As shown in FIG. 23A, at the erase operation, the control gate electrode is set to 0 V and +13 V is applied to the substrate. The floating gate electrode 22 at the moment of voltage application becomes +5.5 V. Consequently, the electric field generated in the tunnel dielectric film 23 becomes 13.6 MV/cm, and the electric field generated in the gate dielectric film 21 becomes 8.0 MV/cm. In this example again, the electric field generated in the tunnel dielectric film 23 is 10 MV/cm or more, so that electrons can be injected from the control gate electrode 24 into the floating gate electrode 22. Injection of electrons into the floating gate electrode 22 is performed due to the electric field generated in the tunnel dielectric film 23, and the electric field generated in the tunnel dielectric film 23 is relaxed to move to the steady state illustrated in FIG. 23B. At this time, the potential of the floating gate electrode becomes 4.2 V, so that the electric field generated in the tunnel dielectric film becomes 10.8 MV/cm and the electric field generated in the gate dielectric film becomes 10 MV/cm. Consequently, erasing can be performed up to the threshold voltage Vₜₕ of +3 V.

Moreover, as shown in FIG. 24A, at the write operation, the substrate potential is set to 0 V, Vₚₐₛₛ of +4 V is applied to the control gate electrode 24N of the nonselected bit, and the program voltage V_{pgm} of +13 V is applied to the control gate electrode 24S of the selected bit. Potentials of the floating gate electrodes 22S and 22N of the selected bit and the nonselected bit at the moment of voltage application are +6.2 V and +1.0 V, respectively. With such voltage distribution, the electric field of 16.9 MV/cm is generated in the tunnel dielectric film 23S of the selected bit having a curvature, and electrons are removed from the floating gate electrode 22S to the control gate electrode 24S. With the removal of electrons from the floating gate electrode 22S to the control gate electrode 24S, the electric field of the tunnel dielectric film 23S is relaxed to move to the steady state illustrated in FIG. 24B.

In the steady state illustrated in FIG. 24B, the potential of the floating gate electrode 22S of the selected bit becomes +8.3 V. With such voltage distribution, the electric field generated in the tunnel dielectric film 23S of the selected bit becomes 11.7 MV/cm. This electric field has a magnitude with which the tunnel current can be caused to flow in the tunnel dielectric film 23S. Consequently, writing can be performed up to the threshold voltage of −5 V in the selected bit.

The electric fields generated in the gate dielectric film 21S of the selected bit at the voltage application and at the steady state are 7.0 MV/cm and 9.4 MV/cm, respectively, which satisfy the condition of avoiding performance of exchanging electrons between the semiconductor substrate 11 and the floating gate electrode 22S. Moreover, the electric field between the adjacent floating gate electrode 22N of the nonselected bit that is erased up to +3 V in which the electric field is the highest and the control gate electrode 24S of the selected bit is smaller than 6.3 MV/cm, enabling to obtain the electric field with which erroneous writing to the floating gate electrode 22N of the nonselected bit due to the voltage applied to the control gate electrode 24S of the selected bit does not occur. Furthermore, the electric field between the control gate electrode 24S of the selected bit and the adjacent control gate electrode 24N of the nonselected bit is 4.7 MV/cm, so that the electric field can be suppressed to the electric field with which leakage current does not flow therebetween.

Moreover, at the voltage application in FIG. 24A, the electric field generated in the tunnel dielectric film 23N of the nonselected bit is 7.4 MV/cm. Consequently, at the voltage application, fluctuation of the voltage of the floating gate electrode 22N in the nonselected bit can be suppressed. As above, it is found that the nonvolatile semiconductor memory device having a structure in the third embodiment can also operate as a memory device.

According to the third embodiment, even with the nonvolatile semiconductor memory device whose half pitch is relatively large, i.e., about 20 nm, by shortening the distance between the floating gate electrodes 22 by pairing two adjacent memory cells MT in the word line direction, and widening the distance from the floating gate electrode 22 of a different pair, it becomes possible to obtain an effect that the tip portion 26 for electron injection having a small curvature can be formed in the control gate electrode 24 in the region between the floating gate electrodes 22 in the pair in addition to the effect in the first embodiment.

### Fourth Embodiment

The first to third embodiments illustrate examples of improving the write/erase characteristics by generating the electric field concentration through changing of the shape of the tunnel dielectric film, and in the fourth embodiment, explanation is given for the case of further improving the write/erase characteristics by changing the structure of the tunnel dielectric film.

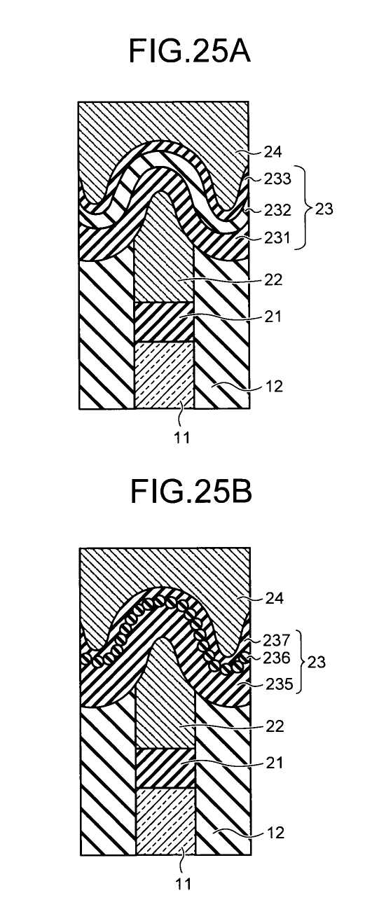

FIG. 25A and FIG. 25B are cross-sectional views schematically illustrating an example of a configuration of a nonvolatile semiconductor memory device according to the fourth embodiment. The nonvolatile semiconductor memory device illustrated in the FIG. 25A and FIG. 25B is the same as that illustrated in FIG. 2 in the first embodiment in the basic structure, however, is different in the structure of the tunnel dielectric film 23. In FIG. 25A, the tunnel dielectric film 23 has an ONO structure in which, for example, an SiO film 231 having a thickness of 3.5 nm, an SiN film 232 having a thickness of 2 nm, and an SiO film 233 having a thickness of 1.5 nm are stacked in order such as that used in the MONOS (Metal-Oxide-Nitride-Oxide-Semiconductor).

Moreover, in FIG. 25B, the tunnel dielectric film 23 has a silicon nanocrystal tunnel structure in which, for example, a silicon nanocrystal 236 having a diameter of around 1 nm is sandwiched between an SiO film 235 having a thickness of 4.5 nm and an SiO film 237 having a thickness of 1 nm.

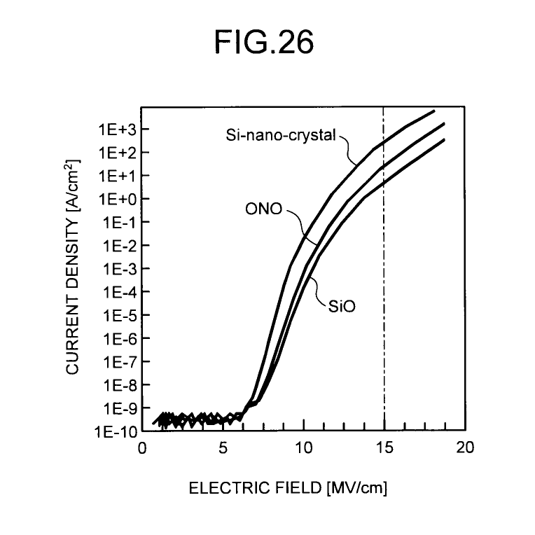

FIG. 26 is a diagram illustrating an example of current-electric field characteristics of the tunnel dielectric film. In FIG. 26, a horizontal axis indicates an electric field applied to the tunnel dielectric film and a vertical axis indicates a current density flowing in the tunnel dielectric film. Moreover, FIG. 26 illustrates the current-electric field characteristics for the cases of using only an SiO film, using the ONO structure in FIG. 25A, and using the silicon nanocrystal tunnel structure in FIG. 25B, as the tunnel dielectric film 23.

As shown in FIG. 26, the same current density can be obtained with a low electric field in the case of using the ONO structure and the silicon nanocrystal tunnel structure compared to the case of using the SiO film as the tunnel dielectric film 23. In other words, an effect is obtained that the write/erase operations can be performed with a further low electric field compared to the case of using the SiO film.

For reducing the operation voltage, it is efficient to cause the electric field to be concentrated on the tunnel dielectric film 23 by thinning the gate dielectric film 21, however, this case has a tradeoff relationship with reduction of the controllability of the channel.

According to the fourth embodiment, because the ONO structure or the silicon nanocrystal tunnel structure is used as the tunnel dielectric film 23 in the structure in the first to third embodiments, an effect is obtained that the tunnel current can flow with a further low electric field compared to the case of using the SiO film as the tunnel dielectric film 23.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device which comprises a memory cell transistor including a stacked gate structure in which a gate dielectric film, a floating gate electrode, a tunnel dielectric film, and a control gate electrode are stacked in order on a channel semiconductor and a shallow trench isolation that separates adjacent memory cell transistors, and in which the tunnel dielectric film and the control gate electrode are connected between the memory cell transistors adjacent via the shallow trench isolation, wherein
each of the floating gate electrode and the control gate electrode includes an electric-field concentrated portion having a curvature on the tunnel dielectric film side,
the electric-field concentrated portion of the floating gate electrode is formed over a forming position of the channel semiconductor,
the electric-field concentrated portion of the control gate electrode is formed over a forming position of the shallow trench isolation, and
a treatment of injecting electrons from the electric-field concentrated portion of the control gate electrode into the floating gate electrode and a treatment of removing electrons from the electric-field concentrated portion of the floating gate electrode to the control gate electrode are controlled by a voltage applied between the channel semiconductor and the control gate electrode.

2. The nonvolatile semiconductor memory device according to claim 1, wherein the tunnel dielectric film has a wave shape in cross section along an adjacent direction of the adjacent memory cell transistors.

3. The nonvolatile semiconductor memory device according to claim 1, wherein
the shallow trench isolation has a structure in which a first isolation dielectric film that separates adjacent memory cell transistors by a first width and a second isolation dielectric film that separates adjacent memory cell transistors by a second width wider than the first width are arranged alternately between a plurality of memory cell transistors, and
the electric-field concentrated portion of the control gate electrode is formed over a forming position of the first isolation dielectric film.

4. The nonvolatile semiconductor memory device according to claim 1, wherein a curvature radius of the electric-field concentrated portion is 40% or less of a film thickness of the tunnel dielectric film.

5. The nonvolatile semiconductor memory device according to claim 1, wherein the gate dielectric film is an ONO film including SiO₂/SiN/SiO₂ or an NONON film including SiN/SiO₂/SiN/SiO₂/SiN.

6. The nonvolatile semiconductor memory device according to claim 1, wherein the tunnel dielectric film is an ONO film including SiO₂/SiN/SiO₂.

7. The nonvolatile semiconductor memory device according to claim 1, wherein the tunnel dielectric film is a film including a silicon nanocrystal tunnel structure in which a silicon nanocrystal is embedded between a first SiO film and a second SiO film.

8. The nonvolatile semiconductor memory device according to claim 1, wherein the memory cell transistor has a sourceless/drainless structure.

9. The nonvolatile semiconductor memory device according to claim 1, wherein the channel semiconductor is a semiconductor substrate, a single-crystal semiconductor substrate of an SOI structure, a polycrystalline semiconductor of a TFT structure, or an amorphous semiconductor of a TFT structure.

10. The nonvolatile semiconductor memory device according to claim 1, which further comprises a transistor of a peripheral circuit portion, wherein the transistor of the peripheral circuit portion includes the same stacked gate structure as the memory cell transistor and has a structure in which the tunnel dielectric film is partially removed to connect the control gate electrode to the floating gate electrode.

11. A method of manufacturing a nonvolatile semiconductor memory device comprising:
forming a gate dielectric film and a floating gate electrode in order on a channel semiconductor;
forming a plurality of isolation trenches that extend in a first direction and reach the channel semiconductor from the floating gate electrode, with intervals in a second direction;
embedding an isolation dielectric film in the isolation trenches;
forming an electric-field concentrated portion having a curvature by processing an upper surface of the floating gate electrode through etching;
forming a tunnel dielectric film and a control gate electrode on the floating gate electrode and the isolation dielectric film; and
patterning a portion from the control gate electrode to at least the floating gate electrode in a line and space shape that extends in the second direction.

12. The method according to claim 11, wherein the forming the isolation trenches includes forming the isolation trenches with predetermined intervals in the second direction.

13. The method according to claim 11, wherein the forming the tunnel dielectric film includes forming the tunnel dielectric film to have a wave shape in cross section along the second direction.

14. The method according to claim 11, wherein the forming the isolation trenches includes forming a first isolation trench that separates adjacent memory cell transistors by a first width and a second isolation trench that separates adjacent memory cell transistors by a second width wider than the first width to be arranged alternately in the second direction.

15. The method according to claim 11, wherein the forming the electric-field concentrated portion includes forming the electric-field concentrated portion so that a curvature radius of the electric-field concentrated portion is 40% or less of a film thickness of the tunnel dielectric film.

16. The method according to claim 11, wherein when the floating gate electrode includes a polycrystalline silicon film, the forming the electric-field concentrated portion includes forming an oxide film on an upper portion of the polycrystalline silicon film by an oxidation treatment, processing the upper portion of the polycrystalline silicon film into a shape having a curvature by slimming, and removing the oxide film.

17. The method according to claim 11, wherein the forming the tunnel dielectric film includes, forming a first SiO film, arranging a silicon nanocrystal on the first SiO film, and forming a second SiO film on the silicon nanocrystal.

18. The method according to claim 11, wherein the forming the control gate electrode includes forming the control gate electrode to have an electric-field concentrated portion having a curvature over the isolation dielectric film.

19. The method according to claim 11, wherein the forming the control gate electrode includes forming the control gate electrode with a polycrystalline silicon film, and after the patterning the portion, a metal film that reacts with silicon to form silicide is formed on the polycrystalline silicon film and a silicide film is formed on an upper portion of the polycrystalline silicon film by performing a heat treatment.

20. The method according to claim 11, wherein the channel semiconductor is a semiconductor substrate, a single-crystal semiconductor substrate of an SOI structure, a polycrystalline semiconductor of a TFT structure, or an amorphous semiconductor of a TFT structure.
